(19) United States
(12) Patent Application Publication
(10) Pub. No.: US 2019/0393449 A1
(43) Pub. Date: Dec. 26, 2019

(54) ORGANIC LIGHT EMITTING DISPLAY DEVICE

(71) Applicant: WUHAN CHINA STAR OPTOELECTRONICS TECHNOLOGY CO., LTD., Hubei (CN)

(72) Inventors: DAN BAI, WUHAN (CN); XIANJIE LI, WUHAN (CN)

(21) Appl. No.: 15/524,910

(22) PCT Filed: Mar. 10, 2017
(86) PCT No.: PCT/CN2017/076312

§ 371 Date: May 5, 2017

(30) Foreign Application Priority Data
Feb. 17, 2017 (CN) 201710086442.6

(51) Int. Cl. H01L 51/52; H01L 27/32

(52) U.S. Cl. CPC H01L 51/5275; H01L 51/5253; H01L 27/323; H01L 27/1218; H01L 2251/5369; H01L 2251/303; H01L 2251/5315; H01L 27/3244

(57) ABSTRACT

An organic light emitting display device is provided, including a substrate, an organic light emitting structure, and a display screen. The organic light emitting structure is disposed between the substrate and the display screen, for emitting light to the display screen. The display screen includes an organic photoresist layer, which is doped with nanoparticles, which have a function of refracting light emitted by the organic light emitting structure toward an outside.

### FIELD OF THE DISCLOSURE

The present disclosure relates to the field of displays, and more particularly to an organic light emitting display device.

### BACKGROUND

OLED (organic light emitting display) display technology differs from traditional LCD displays. It is made without a backlight and uses a very thin organic material coating and glass substrate. When a current passes through, this organic material will light up. Moreover, an OLED display screen can be made lighter and thinner, have a larger viewing angle, and can significantly save energy. Thus, it is generally acknowledged by the industry as a display device provided with the most development potential.

OLED devices include a top-emission type, a bottom-emission type, and a light-penetrating type according to the emission scheme. The top-emission type OLED device emits light from a top electrode side, and its optical radiation includes three modes: an external mode, where the light is transmitted to the air, a waveguide mode, where the light is restricted in the organic material, and a surface plasma mode, where the light is restricted on a surface of metal and dielectric. In the existing top-emission type OLED devices, since the proportion of light in the waveguide mode and the plasma mode is too high and the proportion of light in the external mode is too low, the light extraction efficiency is low.

### SUMMARY OF THE DISCLOSURE

An object of the present disclosure is to provide an organic light emitting display device, by which the light extraction efficiency can be increased.

The present disclosure provides an organic light emitting display device, including: a substrate, an organic light emitting structure, and a display screen;

where the organic light emitting structure is disposed between the substrate and the display screen, and is used for emitting light to the display screen;

the display screen includes an organic photoresist layer, the organic photoresist layer is doped with nanoparticles, which have a function of refracting light emitted by the organic light emitting structure toward an outside; and

a mass fraction of the nanoparticles in the organic photoresist layer is 5%, and a diameter of each nanoparticle is in a range from 200-400 nm.

In the organic light emitting display device of the present disclosure, the nanoparticles are dissolved in the organic photoresist layer by toluene serving as a solvent.

In the organic light emitting display device of the present disclosure, the nanoparticles include titanium dioxide.

In the organic light emitting display device of the present disclosure, the organic light emitting display also includes a thin film packaging layer, where the thin film packaging layer is disposed between the organic light emitting structure and the display screen.

In the organic light emitting display device of the present disclosure, the display screen also includes a capacitance layer, and the capacitance layer is disposed between the thin film packaging layer and the organic photoresist layer.

In the organic light emitting display device of the present disclosure, the capacitance layer includes a plurality of capacitors, and each capacitor includes a first metal layer, a second metal layer, and an insulation layer disposed between the first metal layer and the second metal layer.

In the organic light emitting display device of the present disclosure, the organic light emitting display device also includes a low temperature polycrystalline silicon thin film transistor, where the low temperature polycrystalline silicon thin film transistor is disposed between the substrate and the organic light emitting structure.

In the organic light emitting display device of the present disclosure, the organic light emitting display device also includes a polyimide layer, where the polyimide layer is disposed between the substrate and the low temperature polycrystalline silicon thin film transistor.

In the organic light emitting display device of the present disclosure, the organic light emitting structure is a top-emission organic light emitting structure.

The present disclosure also provides an organic light emitting display device, including: a substrate, an organic light emitting structure, and a display screen;

where the organic light emitting structure is disposed between the substrate and the display screen, and is used for emitting light to the display screen; and

the display screen includes an organic photoresist layer, the organic photoresist layer is doped with nanoparticles, which have a function of refracting light emitted by the organic light emitting structure toward an outside.

In the organic light emitting display device of the present disclosure, a mass fraction of the nanoparticles in the organic photoresist layer is 5%.

In the organic light emitting display device of the present disclosure, the nanoparticles are dissolved in the organic photoresist layer by toluene serving as a solvent.

In the organic light emitting display device of the present disclosure, a diameter of each nanoparticle is in a range from 200-400 nm.

In the organic light emitting display device of the present disclosure, the nanoparticles include titanium dioxide.

In the organic light emitting display device of the present disclosure, the organic light emitting display device also includes a thin film packaging layer, where the thin film packaging layer is disposed between the organic light emitting structure and the display screen.

In the organic light emitting display device of the present disclosure, the display screen also includes a capacitance layer, and the capacitance layer is disposed between the thin film packaging layer and the organic photoresist layer.

In the organic light emitting display device of the present disclosure, the capacitance layer includes a plurality of capacitors, and each capacitor includes a first metal layer, a second metal layer, and an insulation layer disposed between the first metal layer and the second metal layer.

In the organic light emitting display device of the present disclosure, the organic light emitting display device also includes a low temperature polycrystalline silicon thin film transistor, where the low temperature polycrystalline silicon thin film transistor is disposed between the substrate and the organic light emitting structure.

In the organic light emitting display device of the present disclosure, the organic light emitting display device also includes a polyimide layer, where the polyimide layer is disposed between the substrate and the low temperature polycrystalline silicon thin film transistor.

In the organic light emitting display device of the present disclosure, the organic light emitting structure is a top-emission organic light emitting structure.

In comparison to an organic light emitting display device in the prior art, in the organic light emitting display device of the present disclosure, by adding nanoparticles into the organic photoresist layer of the display screen, the light extraction efficiency of the organic light emitting structure is increased.

In order to make the present disclosure more clear, preferred embodiments and the drawings thereof are described in detail below.

### BRIEF DESCRIPTION OF THE DRAWINGS

FIG. 1 is a schematic diagram of an organic light emitting display device according to an embodiment of the present disclosure.

FIG. 2 is a schematic diagram of an organic light emitting display device according to another embodiment of the present disclosure.

FIG. 3 is a schematic diagram of an organic light emitting display device according to still another embodiment of the present disclosure.

FIG. 4 is a schematic diagram of an organic light emitting display device according to a further embodiment of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto.

In the drawings, the same reference symbol represents the same or similar components.

Reference herein to “embodiment” means that a particular feature, structure, or characteristic described in connection with the embodiment can be included in at least one embodiment of the invention. The appearances of this phrase in various places in the specification are not necessarily all referring to the same embodiment, nor are separate or alternative embodiments mutually exclusive of other embodiments. The embodiments described herein, explicitly and implicitly understood by one skilled in the art, may be combined with other embodiments.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

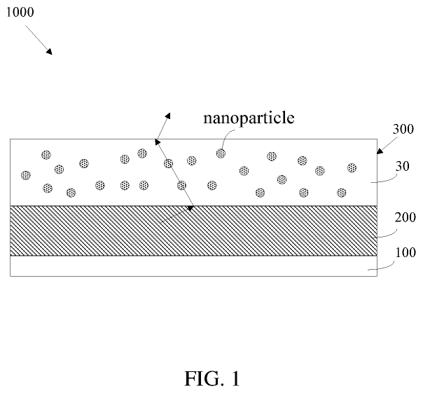

FIG. 1 is a schematic diagram of an organic light emitting display device according to an embodiment of the present disclosure. The organic light emitting display device 1000 includes a substrate 100, an organic light emitting structure 200, and a display screen 300.

The organic light emitting structure 200 is disposed between the substrate 100 and the display screen 300, where the substrate 100 is a glass substrate.

The organic light emitting structure 200 is a sandwich structure, and includes an anode, a cathode, and a light-emitting layer sandwiched between the anode and the cathode. Specifically, a transparent electrode made of indium tin oxide material serves as the anode, and then a single layer or a multilayer organic thin film is formed on the anode by a vapor deposition method or a spin coating method to form the light-emitting layer. Finally, a metal having a low work function, such as magnesium, calcium, etc., is formed on the light-emitting layer to serve as cathode.

In some embodiments, the organic light emitting structure 200 is a top-emission organic light emitting structure. That is, the light emitted from the light-emitting layer emits to the display screen 300 side. In some embodiments, the organic light emitting structure 200 is an active matrix organic light emitting diode (AMOLED).

The display screen 300 includes an organic photoresist layer 30. The organic photoresist layer 30 is doped with nanoparticles, which have a function of refracting light emitted from the organic light emitting structure to the display screen 300 toward an outside.

In some embodiments, a diameter of each nanoparticle is in a range from 200-400 nm. The nanoparticles are dissolved in the organic photoresist layer 30 by toluene serving as a solvent. The nanoparticles include nanoparticles having a high refractive index, such as titanium dioxide, etc.

Specifically, the nanoparticles are dissolved in the organic photoresist by toluene serving as a solvent, so that the mass fraction of the nanoparticle is up to 5%, and then are fully agitated, such that the nanoparticles are evenly dispersed in the organic photoresist, thereby forming a scattering film having a high refractive index. Finally, it is coated on the organic light emitting structure 200.

As shown in FIG. 1, when the organic light emitting structure 200 emits light to the display screen 300, and then the light passes through the organic photoresist layer 30, the light will be refracted toward an outside by the nanoparticles, so that more light is scattered out, thereby increasing the light extraction efficiency of the organic light emitting structure from 40% to 60%.

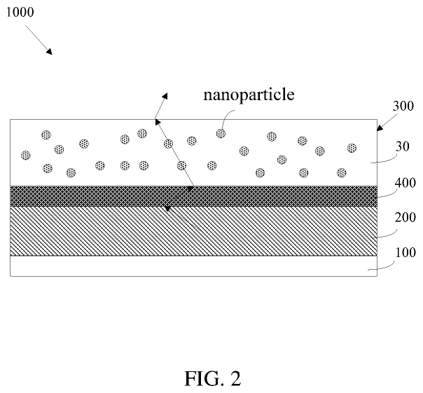

FIG. 2 is a schematic diagram of an organic light emitting display device according to another embodiment of the present disclosure. Since the metal cathode of the organic light emitting structure 200 is generally made of aluminum, magnesium, calcium, and other active metals, it is very easy to react with water vapor which infiltrates from the outside atmosphere, thereby affecting the charge injection. At the same time, infiltration of water and oxygen will react with organic materials, thereby decreasing the performance of the device. Therefore, as shown in FIG. 2, the thin film packaging layer 400 is provided in the organic light emitting display device 1000 by using a thin film packaging technique. The thin film packaging layer 400 is disposed between the organic light emitting structure 200 and the display screen 300 for protecting the organic light emitting structure 200 from external moisture and oxygen, thereby functioning as a package.

In some embodiments, the organic light emitting fabric 200 may also be packaged by using techniques such as metal can packaging technology, glass packaging technology, and hybrid packaging technology, etc.

When the organic light emitting structure 200 emits light to the display screen 300, the light passes through the thin film packaging layer 400 and the organic photoresist layer 30, sequentially, where the light is firstly refracted by the thin film packaging layer 400 toward to the organic photoresist layer 30, and then the light is refracted by the nanoparticles in the organic photoresist layer 30 toward an outside, so that more light is scattered out, thereby increasing the light extraction efficiency of the organic light emitting structure from 40% to 60%.

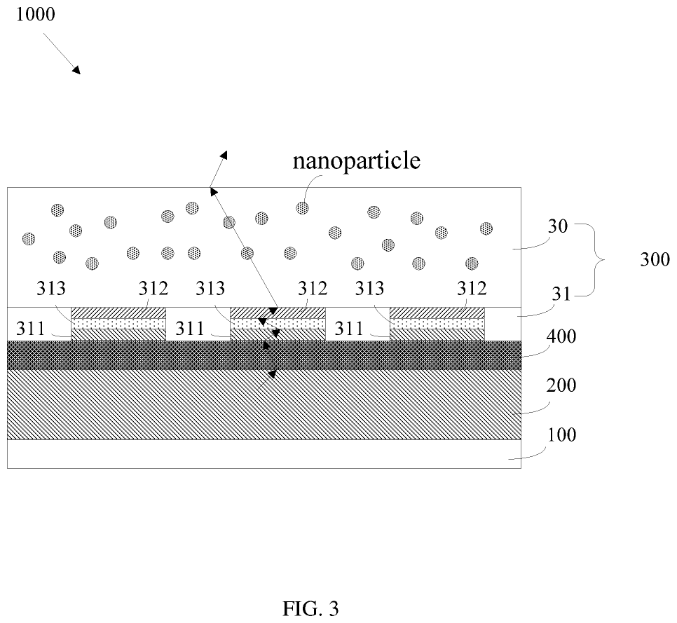

In some embodiments, the display screen 300 is a touch panel. Refer to FIG. 3, the display screen 300 also includes a capacitance layer 31, which is disposed between the thin film packaging layer 400 and the organic photoresist layer 30, for detecting touch capacitance. The capacitance layer 31 includes a plurality of capacitors. Each capacitor includes a first metal layer 311, a second metal layer 312, and an insulation layer 313 disposed between the first metal layer 311 and the second metal layer 312. The first metal layer 311 and the second metal layer 312 are made of titanium/aluminum/titanium material, and the insulation layer 313 is made of silicon nitride material.

When the organic light emitting structure 200 emits light to the display screen 300, the light passes through the thin film packaging layer 400, the capacitance layer 31, and the organic photoresist layer 30, sequentially, where the light is firstly refracted by the thin film packaging layer 400 and the capacitance layer 31 toward to the organic photoresist layer 30, and then the light is refracted by the nanoparticles in the organic photoresist layer 30 toward an outside, so that more light is scattered out, thereby increasing the light extraction efficiency of the organic light emitting structure from 40% to 60%.

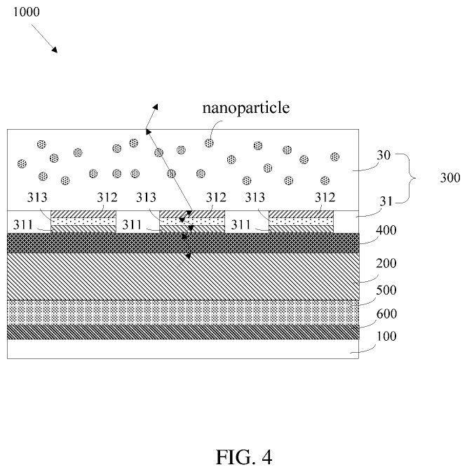

In some embodiments, the organic light emitting display device 1000 also includes a thin film transistor. Refer to FIG. 4, the organic light emitting display device 1000 also includes a low temperature polycrystalline silicon thin film transistor 500, which is disposed between the substrate 100 and the organic light emitting structure 200.

In some embodiments, referring to FIG. 4, the organic light emitting display device 1000 also includes a polyimide (PI) layer 600, which is disposed between the substrate 100 and the low temperature polycrystalline silicon thin film transistor 500. Specifically, the substrate 100 is firstly cleaned, and then a PI solution is coated on the substrate 100. Finally, the PI layer is formed by heating.

In some embodiments, the PI layer may be replaced with a coating of polyimide, polyacrylic resin, and polyvinylacohol.

In the organic light emitting display device of the present disclosure, by adding nanoparticles into the organic photoresist layer of the display screen, the light extraction efficiency of the organic light emitting structure is increased.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

What is claimed is:

1. An organic light emitting display device, comprising: a substrate, an organic light emitting structure, and a display screen;
wherein the organic light emitting structure is disposed between the substrate and the display screen, and is used for emitting light to the display screen;
the display screen comprises an organic photoresist layer, the organic photoresist layer is doped with nanoparticles, which have a function of refracting light emitted by the organic light emitting structure toward an outside; and
a mass fraction of the nanoparticles in the organic photoresist layer is 5%, and a diameter of each nanoparticle is in a range from 200-400 nm.

2. The organic light emitting display device as claimed in claim 1, wherein the nanoparticles are dissolved in the organic photoresist layer by toluene serving as a solvent.

3. The organic light emitting display device as claimed in claim 1, wherein the nanoparticles comprise titanium dioxide.

4. The organic light emitting display device as claimed in claim 1, further comprising a thin film packaging layer, wherein the thin film packaging layer is disposed between the organic light emitting structure and the display screen.

5. The organic light emitting display device as claimed in claim 4, wherein the display screen also comprises a capacitance layer, and the capacitance layer is disposed between the thin film packaging layer and the organic photoresist layer.

6. The organic light emitting display device as claimed in claim 5, wherein the capacitance layer comprises a plurality of capacitors, and each capacitor comprises a first metal layer, a second metal layer, and an insulation layer disposed between the first metal layer and the second metal layer.

7. The organic light emitting display device as claimed in claim 1, further comprising a low temperature polycrystalline silicon thin film transistor, wherein the low temperature polycrystalline silicon thin film transistor is disposed between the substrate and the organic light emitting structure.

8. The organic light emitting display device as claimed in claim 7, further comprising a polyimide layer, wherein the polyimide layer is disposed between the substrate and the low temperature polycrystalline silicon thin film transistor.

9. The organic light emitting display device as claimed in claim 1, wherein the organic light emitting structure is a top-emission organic light emitting structure.

10. An organic light emitting display device, comprising: a substrate, an organic light emitting structure, and a display screen;
wherein the organic light emitting structure is disposed between the substrate and the display screen, and is used for emitting light to the display screen; and
the display screen comprises an organic photoresist layer, the organic photoresist layer is doped with nanoparticles, which have a function of refracting light emitted by the organic light emitting structure toward an outside.

11. The organic light emitting display device as claimed in claim 10, wherein a mass fraction of the nanoparticles in the organic photoresist layer is 5%.

12. The organic light emitting display device as claimed in claim 10, wherein the nanoparticles are dissolved in the organic photoresist layer by toluene serving as a solvent.

13. The organic light emitting display device as claimed in claim 10, wherein a diameter of each nanoparticle is in a range from 200-400 nm.

14. The organic light emitting display device as claimed in claim 10, wherein the nanoparticles comprise titanium dioxide.

15. The organic light emitting display device as claimed in claim 10, further comprising a thin film packaging layer, wherein the thin film packaging layer is disposed between the organic light emitting structure and the display screen.

16. The organic light emitting display device as claimed in claim 15, wherein the display screen also comprises a capacitance layer, and the capacitance layer is disposed between the thin film packaging layer and the organic photoresist layer.

17. The organic light emitting display device as claimed in claim 16, wherein the capacitance layer comprises a plurality of capacitors, and each capacitor comprises a first metal layer, a second metal layer, and an insulation layer disposed between the first metal layer and the second metal layer.

18. The organic light emitting display device as claimed in claim 10, further comprising a low temperature polycrystalline silicon thin film transistor, wherein the low temperature polycrystalline silicon thin film transistor is disposed between the substrate and the organic light emitting structure.

19. The organic light emitting display device as claimed in claim 18, further comprising a polyimide layer, wherein the polyimide layer is disposed between the substrate and the low temperature polycrystalline silicon thin film transistor.

20. The organic light emitting display device as claimed in claim 10, wherein the organic light emitting structure is a top-emission organic light emitting structure.
